(19) United States
(12) Patent Application Publication
(10) Pub. No.: US 2010/0060338 A1
(43) Pub. Date: Mar. 11, 2010

(54) LEVEL SHIFTER WITH REDUCED LEAKAGE

(75) Inventors: Keng Leong FONG, Sunnyvale, CA (US); I-Chang WU, Fremont, CA (US)

Correspondence Address: SAWYER LAW GROUP PC, 2465 E. Bayshore Road, Suite No. 406, PALO ALTO, CA, 94303, US

(73) Assignee: RALINK TECHNOLOGY CORPORATION, Cupertino, CA (US)

(21) Appl. No.: 12/209,140

(22) Filed: Sep. 11, 2008

(51) Int. Cl. H03L 5/00

(52) U.S. Cl. 327/333

(57) ABSTRACT

The present invention relates generally to the level shifter circuits and more specifically to improved level shifter circuits providing for reduced leakage current and reduced power consumption. In one or more implementations, a method, apparatus and computer program product for level shifting input voltages by minimizing current leakage of a circuit coupled with an improved level shifting circuit is provided for. In one implementation the method includes providing a low voltage domain of the circuit, and providing for turning off the transistor if the low voltage domain of the circuit is not stable, and turning on the transistor if the low voltage domain of the circuit is stable.

### FIELD OF THE INVENTION

The present invention relates generally to the level shifter circuits and more specifically to improved level shifter circuits providing for reduced leakage current and reduced power consumption.

### BACKGROUND OF THE INVENTION

In digital circuits that have multiple power domains operating with differing power supply voltages, level shifters are often used to convert logic signals from one power domain to another. For example, it will be understood by those skilled in the art that many digital circuits may have 1.2V and 3.3V power domains in which level shifter circuits (i.e., level shifters) are needed to convert 1.2V digital signals to 3.3V. In a conventional approach, the level shifter circuit typically is employed in such digital circuits to convert an output signal from the lower voltage operating circuit to the higher voltage operating circuit (i.e., or “level”) so it may be used in the higher voltage operating circuit and/or be provided for output via an external output such as a pin, port, or the like.

For instance, one conventional approach is to have an output buffer circuit employs a level shifter circuit coupled to a power supply which has a voltage different from the source voltage. In this example, in response to the values of the input voltage signals, the level shifter circuit attempts to use a set of output drivers to provide adequate output voltages.

An operational deployment of such conventional level shifter circuits may include complementary metal-oxide semiconductor (CMOS) integrated circuits, in which a CMOS level shifter is used to interface a current CMOS circuit with integrated circuit (IC) devices manufactured under previous technologies. In such a scenario, it is often found that the CMOS voltage levels in IC devices from the current technology are different from the CMOS voltage levels in IC devices from previous technologies. Therefore, in one approach, level shifters are used to provide for interfacing between different CMOS voltage levels, such that present IC devices often include output buffer circuits that are capable of driving voltages greater than the core voltage.

FIG. 1 sets forth a conventional level shifter circuit (100). Transistor M1 (110) and M2 (120) are arranged to amplify the complementary input signals input1 (130) and input2 (140), in which each is typically assumed by designers to be logically well-defined (i.e., either Vcc or Gnd, and complementary to one another). From the Figure, transistors M3 (150) and M4 (160) are generally arranged in the conventional circuit to form a cross-coupled latch that attempts to result in the output voltages Output1 (170) and Output2 (180). It will be appreciated by those skilled in the art that other variations and arrangements of a conventional level shifter circuit are possible than the example set forth in FIG. 1.

In practice, however, such assumptions are erroneous, Often, in conventional level shifter circuits, the voltages of Input1 (130) and Input2 (140) are not logically well-defined (a value in between Vcc and Gnd, and not complementary to one another). This often results as the power supply of the logic gates driving Input1 and Input2 is turned off.

In one example where the voltages of Input1 and lnput2 are not logically well-defined, Output2 and Output1 are latched to ground and Vcc respectively. In this scenario, using FIG. 1 as a reference, where the voltage of Input1 is not grounded, a leakage current path traverses generally from power supply, transistor M3 and transistor M1 to ground. In this example, power consumption is also increased as a result of current leakage.

Accordingly, what is desired is an approach which provides for reduced leakage current and reduced power consumption in situations in which input voltages may not be logically well-defined. The present invention addresses such a need.

### SUMMARY OF THE INVENTION

An approach of level shifting input voltages by minimizing current leakage of a circuit coupled with an improved level shifting circuit having a switching transistor capable of switching current to a level shifting sub-circuit configured therewith, and a low voltage domain, is provided for.

In one implementation, an apparatus having an improved level shifting circuit including a switching transistor configured with a level shifting sub-circuit, for minimizing current leakage, the circuit comprising: a switching transistor capable of switching current to a level shifting sub-circuit configured therewith, turning off the switching transistor if the low voltage domain of the coupled circuit is not stable, and turning on the switching transistor if the low voltage domain of the coupled circuit is stable.

In another implementation, an improved level shifting circuit including a switching transistor configured with a level shifting circuit for minimizing current leakage, the improved circuit comprising: a switching transistor capable of switching current to a level shifting circuit electronically coupled and in communication therewith, turning off the switching transistor if the low voltage domain of the coupled circuit is not stable and turning on the switching transistor if the low voltage domain of the connected circuit is stable.

In a further implementation, an electronic circuit providing for reduced current leakage, having configured therein, a circuit for level shifting and a switching transistor in communication with the circuit for level shifting, is provided.

### BRIEF DESCRIPTION OF THE DRAWINGS

FIG. 1 shows a conventional level shifter circuit.

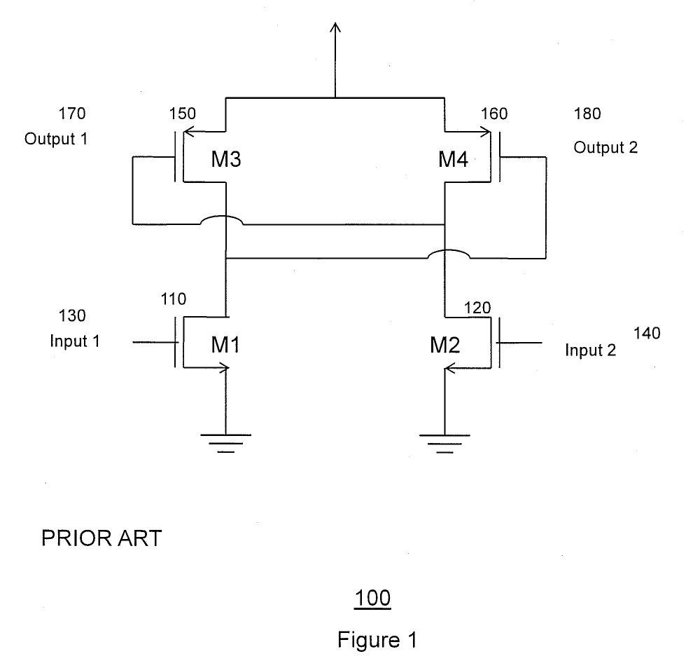

FIG. 2 depicts a circuit according to one implementation of the present invention, transitioning from a low voltage domain to a high voltage domain using a p-channel metal-oxide-semiconductor (PMOS) transistor as the switch (i.e., switching transistor).

FIG. 3 depicts a circuit according to another implementation of the present invention, transitioning signals from a low voltage domain to a high voltage domain using an n-channel MOS (NMOS) transistor as the switch (i.e., switching transistor).

### DETAILED DESCRIPTION OF PREFERRED EMBODIMENTS

The present invention relates generally to the conventional level shifter and more specifically to improved level shifter circuits providing for reduced leakage current and reduced power consumption. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

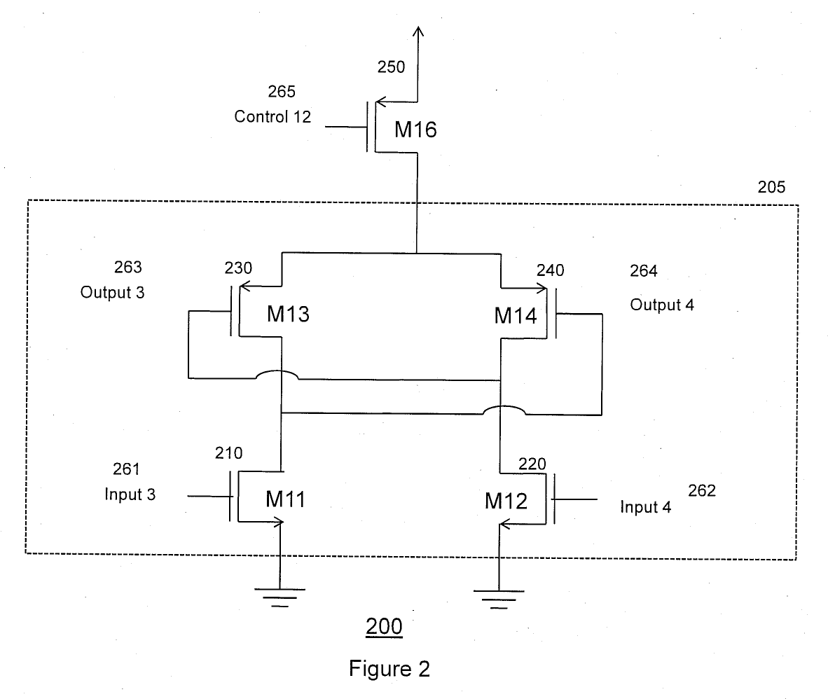

FIG. 2 depicts a circuit 200 according to one implementation of the present invention, transitioning from a low voltage domain to a high voltage domain.

From FIG. 2, an improved level shifter configuration, where transistor M16 (250) is added to a level shifter circuit, such as the circuit of the conventional level shifter. In this manner, from FIG. 2, the present invention prevents current leakage and unnecessary power consumption by turning off the level shifting capabilities and the leakage path during a period in which the input voltage from the power supply is not logically well-defined. Further from FIG. 2, once the input voltage (i.e., low voltage domain) is determined to be stable, the level shifting capabilities of the present invention are turned on since the input voltage from the power supply is then logically well-defined.

From FIG. 2, a level shifting portion of the circuit of the present invention is set forth at 205. Further from FIG. 2, a transistor M11 (210) and M12 (220) are arranged to amplify the complementary input signals input3 (261) and input4 (262). From FIG. 2, transistors M13 (230) and M14 (240) are arranged in to form a cross-coupled latch that attempts to result in the output voltages Output3 (263) and Output4 (264). Further from FIG. 2, transistor M16 (250) is arranged to be in connectivity with transistor M13 (230) and M14 (240). A control signal (i.e., Control12) is set forth at 265.

It will be appreciated by those skilled in the art that the present invention, in one or more implementations provides for reduced leakage current and in certain implementations, the elimination of leakage current is also achieved. For instance, from FIG. 2, when Control12 (265) is pulled “high”, transistor M16 (250) is turned off which results in reduction or elimination of leakage current from power supply to ground. By further example, from FIG. 2, when Control12 (265) is pulled “low”, transistor M16 (250) is turned on and the circuit of the implementation provides operational capabilities of converting an output signal from a lower voltage operating circuit to a higher voltage operating circuit.

Operationally, the transistor M16 (250) of FIG. 2 may be turned on or off by a variety of means including but not limited to: power detection circuitry, switching circuitry, or other circuitry or software configurably arranged with the transistor M16 or circuit of the present invention.

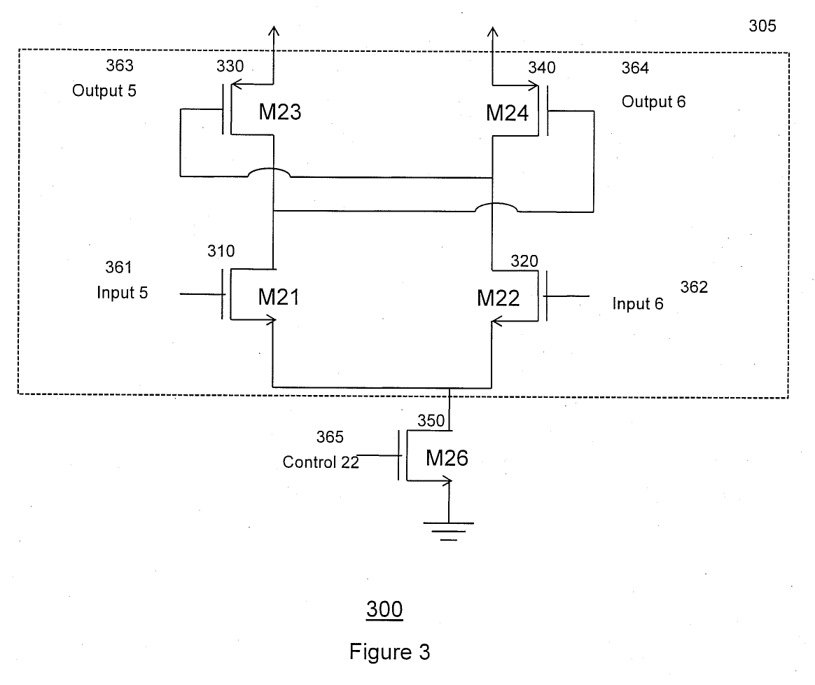

FIG. 3 depicts a circuit 300 according to another implementation of the present invention, transitioning signals from a low voltage domain to a high-voltage domain.

From FIG. 3, an improved level shifter configuration 300 is set forth where transistor M16 (250) is added to a conventional level shifter arrangement. In this manner, from FIG. 3, the present invention prevents current leakage and unnecessary power consumption by turning off the level shifting capabilities and the leakage path during a period in which the input voltage from the power supply is not logically well-defined. Further from FIG. 3, once the input voltage is determined to be stable, the level shifting capabilities of the present invention are turned on since the input voltage from the power supply is then logically well-defined. Determination of the stability of input voltage, such as stability determination and determination means, may be accomplished by voltage or power detection circuitry, switching circuitry, or other circuitry or software configurably arranged to measure, sense or otherwise comparatively determine the stability of the input-signal voltage. For example, the determination means may further comprise providing for reassessing by re-determining whether the low voltage domain of a circuit is stable, and thereafter, providing for any of, in relation to the re-determination, turning off the switching transistor if the low voltage domain of a circuit is not stable, turning on the switching transistor if the low voltage domain of a circuit is stable, and taking no action with respect to the switching transistor.

From FIG. 3, a level shifting portion of the circuit of the present invention is set forth at 305. Further from FIG. 3, transistors M21 (310) and M22 (320) are arranged to amplify the complementary input signals input5 (361) and input6 (362). From FIG. 3, transistors M23 (330) and M24 (340) are arranged in to form a cross-coupled latch that attempts to result in the output voltages Output5 (363) and Output6 (364). Further from FIG. 3, transistor M26 (350) is arranged to be in connectivity with transistor M21 (310) and M22 (320). A control signal (i.e., Control22) is set forth at 365.

Operationally, the transistor M26 (350) of FIG. 3 may be turned on or off by a variety of means including but not limited to: power detection circuitry, switching circuitry, or other circuitry or software configurably arranged with the transistor M16 or circuit of the present invention.

It will be appreciated by those skilled in the art that the present invention, in one or more implementations provides for reduced leakage current and in certain implementations, the elimination of leakage current is also achieved. For instance, from FIG. 3, when Control22 is pulled “low,” transistor M26 (350) is turned off which results in reduction or elimination of leakage current from power supply to ground. When Control22 is pulled “high,” transistor M26 (350) is turned on and the circuit of the implementation provides operational capabilities of converting an output signal from a lower voltage operating circuit to a higher voltage operating circuit.

The present invention may be incorporated into various electronic devices, systems and/or software and computer program products associated with the purposes of the invention, without limitation. The present invention may comprise a circuit, an integrated circuit, and/or be integrated therewith as well.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

The present invention in one or more implementations may be implemented as part of an electronic circuit, device, and/or semiconductor, and in other arrangements. The present invention is operable in and with conventional level shifter circuits, devices configured with conventional circuits and new semiconductor devices. The present invention is also operable in and with circuits which provide for logically well-defined input voltages although benefits of the present invention are more aptly derived in circuits having input voltages which may not be logically well-defined during certain periods of operation. It will be appreciated by those skilled in the art that the present invention, in various implementations and arrangements, prevents leakage current and reduces power consumption caused by leakage current.

As used herein, transistors of the present invention may include any of p-channel metal-oxide-semiconductor (PMOS), n-channel MOS (NMOS) transistors, and other metal-oxide-semiconductor (MOS) or other transistor types, in any arrangement or combination to provide operability of the present invention.

As used herein the term “logically well-defined” with respect to input voltages is intended to mean input voltages having a value either of Vcc or ground (i.e., Gnd), and input voltages will be complementary of one another (i.e., one is Vcc and the other is Gnd). A value in between Vcc and Ground cannot be considered logically well-defined.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. An apparatus having an improved level shifting circuit including a switching transistor coupled to a level shifting sub-circuit, for minimizing current leakage, the apparatus comprising: a switching transistor coupled to a low voltage domain of a coupled circuit wherein the switching transistor is turned off if the low voltage domain of the coupled circuit is not stable, and the switching transistor is turned on if the low voltage domain of the coupled circuit is stable.

2. The apparatus of claim 1, wherein the switching transistor operates to turn on or turn off the current to the level shifting sub-circuit.

3. The apparatus of claim 1, wherein the switching transistor is a p-channel metal-oxide-semiconductor field-effect transistor (PMOSFET or PMOS).

4. The apparatus of claim 1, wherein the switching transistor is a n-channel MOSFET (NMOSFET or NMOS).

5. The apparatus of claim 1, wherein the switching transistor is one of a p-channel field-effect transistor (PFET) transistor, a n-channel FET (NFET) transistor, or a transistor of a field-effect transistor type (FET).

6. The apparatus of claim 1, wherein the switching transistor is configurably arranged with the level shifting sub-circuit to turn on or turn off the current to the level shifting sub-circuit.

7. The apparatus of claim 1, wherein the switching transistor isolates the level shifter sub-circuit from one or more voltage sources.

8. The apparatus of claim 1, wherein the level shifting sub-circuit comprises: an input unit for receiving a first signal that varies between a first voltage source and a second voltage source; and a level shifter unit for converting a first signal that varies between the first voltage source and the second voltage source to a level-shifted signal that varies between the first voltage source and a third voltage source, the level shifter circuit including a first transistor of a first conductivity type having a source electrode coupled to the first voltage source, a second transistor of the first conductivity type having a source electrode coupled to the first voltage source.

9. The apparatus of claim 8, wherein when the switching transistor is a PMOS transistor set to a high impedance setting, the switching transistor is turned off.

10. An improved level shifting circuit including a switching transistor coupled to a level shifting circuit for minimizing current leakage, the improved circuit comprising: a switching transistor capable of switching current to a level shifting circuit electronically coupled and in communication therewith, and switching means providing for turning off the switching transistor if the low voltage domain of the coupled circuit is not stable and turning on the switching transistor if the low voltage domain of the connected circuit is stable.

11. The circuit of claim 10, wherein the switching transistor operates to turn on or turn off the current to the level shifting circuit.

12. The circuit of claim 10, wherein the switching transistor is a p-channel metal-oxide-semiconductor field-effect (PMOSFET or PMOS) transistor.

13. The circuit of claim 10, wherein the switching transistor is a n-channel MOSFET (NMOSFET or NMOS).

14. The circuit of claim 10, wherein the switching transistor is one of a p-channel metal-oxide-semiconductor field-effect (PMOSFET) transistor, a n-channel MOSFET (NMOSFET or NMOS) transistor, or a transistor of field-effect (FET) transistor type.

15. The circuit of claim 10, wherein the switching transistor is configurably arranged with the level shifting circuit to turn on or turn off the current to the level shifting circuit.

16. The circuit of claim 10, wherein the switching transistor isolates the level shifting circuit from one or more voltage sources.

17. The apparatus of claim 10, wherein the level shifting circuit comprises: an input unit for receiving a first signal that varies between the first voltage source and the second voltage source; and a level shifter unit for converting a first signal that varies between a first voltage source and a second voltage source to a level-shifted signal that varies between the first voltage source and a third voltage source, the level shifter circuit including a first transistor of a first conductivity type having a source electrode coupled to the first voltage source, a second transistor of the first conductivity type having a source electrode coupled to the first voltage source.

18. The circuit of claim 17, wherein when the switching transistor is a PMOS transistor set to a high impedance setting, the switching transistor is turned off, and when the switching transistor is a NMOS transistor set to a high impedance setting, the transistor is turned off.

19. An electronic circuit providing for reduced current leakage, having configured therein, a circuit for level shifting and a switching transistor in communication with the circuit for level shifting, the electronic circuit comprising: the switching transistor for switching current to the circuit for level shifting, an input voltage to the electronic circuit, wherein the switching transistor switches to an “OFF” state if the input voltage is not stable, or to an “ON” state if the input voltage is stable.

20. The electronic circuit of claim 19, wherein the switching transistor is one of a p-channel metal-oxide-semiconductor field-effect (PMOSFET or PMOS) transistor, a n-channel MOSFET (NMOSFET or NMOS) transistor, or a field-effect transistor (MOS) type.

21. The apparatus of claim 8, wherein when the switching transistor is an-NMOS transistor set to a high impedance setting, the transistor is turned off.
